(19) United States
(12) Patent Application Publication
(10) Pub. No.: US 2024/0201257 A1
(43) Pub. Date: Jun. 20, 2024

(54) AUTOMATED TEST PATTERN GENERATION FOR TESTING DESIGN REDACTING RECONFIGURABLE HARDWARE

(71) Applicant: University of Florida Research Foundation, Incorporated, Gainesville, FL (US)

(72) Inventors: Greg M. Stitt, Gainesville, FL (US); Swarup Bhunia, Gainesville, FL (US); Naren Vikram Raj Masna, Gainesville, FL (US); Aritra Dasgupta, Gainesville, FL (US)

(21) Appl. No.: 18/536,973

(22) Filed: Dec. 12, 2023

Related U.S. Application Data
(60) Provisional application No. 63/432,584, filed on Dec. 14, 2022.

(51) Int. Cl. G01R 31/3183; G01R 31/3185

(52) U.S. Cl. CPC G01R 31/318307; G01R 31/318525; G01R 31/318536

(57) ABSTRACT

A method and system are directed to testing reconfigurable hardware designs, the method comprising inserting a scan chain into a reconfigurable hardware design associated with an integrated circuit comprising a redacted design; generating, using an automatic test pattern generation (ATPG) system, one or more test patterns and one or more bitstreams; receiving one or more primary outputs and contents of the scan chain from the reconfigurable hardware design by applying the one or more test patterns and the one or more bitstreams to the reconfigurable hardware design based on an ATPG test method of a plurality of ATPG test methods and a test architecture of a plurality of test architectures; comparing the one or more outputs and contents of the scan chain with one or more respective expected outcomes; and determining one or more faults associated with the reconfigurable hardware design based on the comparison.

### CROSS REFERENCE TO RELATED APPLICATION

This application claims the priority of U.S. Provisional Application No. 63/432,584, entitled “AUTOMATED TEST PATTERN GENERATION FOR TESTING DESIGN REDACTING RECONFIGURABLE HARDWARE,” filed on Dec. 14, 2022, the disclosure of which is hereby incorporated by reference in its entirety.

### GOVERNMENT SUPPORT

This invention was made with government support under Agreement No. N00164-19-9-0001, awarded by NSWC Crane Division. The government has certain rights in the invention.

### TECHNICAL FIELD

The present application relates hardware testing, and more particularly to improvements in automated test-pattern generation for design redacted reconfigurable hardware.

### BACKGROUND

Integrating reconfigurable hardware into application-specific integrated circuits (ASICs) in the form of embedded field-programmable gate arrays (eFPGAs) is becoming increasingly common due to security advantages that protect a design's confidentiality against reverse engineering and piracy attacks by hiding (e.g., redacting) the original design. However, these advantages come at the cost of increased testing challenges. For example, FPGAs may use built-in self-test (BIST) methods, but such methods often require partial reconfiguration or other specialized functionality, which may not be necessary for many use cases of embedded reconfigurable hardware, especially ones that do not use regular fabric-like architectures.

An alternative is automatic test-pattern generation (ATPG)—a process for determining a minimal set of tests that expose faults, which may be especially challenging for reconfigurable hardware, despite numerous effective strategies for fixed-logic ASICs. In particular, a limitation of current ATPG methods is the requirement for analyzing application functionality to determine test patterns. With reconfigurable hardware, an application's functionality is not revealed by the circuit's structure and is instead specified at runtime by shifting a set of bits (i.e., a bitstream) into a serially loaded set of configuration flip-flops. Although a bitstream could potentially be provided to perform ATPG for reconfigurable hardware, such an approach is not ideal since is does not test the entire fault space. More importantly, for redacted intellectual property (IP), the bitstream cannot be used since this would reveal the original design. Thus, there is a need for improved ATPG test methods that achieve a desired fault coverage while minimizing testing time.

### BRIEF SUMMARY

Various embodiments described herein relate to methods, apparatus, systems, computing devices, computing entities, and/or the like for testing reconfigurable hardware designs.

According to one embodiment, a method comprises inserting, by one or more processors, a scan chain into a reconfigurable hardware design associated with an integrated circuit comprising a redacted design; generating, by the one or more processors and using an automatic test pattern generation (ATPG) system, one or more test patterns and one or more bitstreams; receiving, by the one or more processors, one or more primary outputs and contents of the scan chain from the reconfigurable hardware design by applying the one or more test patterns and the one or more bitstreams to the reconfigurable hardware design based on an ATPG test method of a plurality of ATPG test methods and a test architecture of a plurality of test architectures; comparing the one or more outputs and contents of the scan chain with one or more respective expected outcomes; and determining one or more faults associated with the reconfigurable hardware design based on the comparison.

In some embodiments, the method further comprises, based on the ATPG test method of the plurality of ATPG test methods comprising a base ATPG test method, treating contents of one or more configuration flip-flops associated with the reconfigurable hardware design as one or more primary inputs. In some embodiments, the method further comprises, based on the ATPG test method of the plurality of ATPG test methods comprising a shift ATPG test method, treating contents of one or more configuration flip-flops associated with the reconfigurable hardware design as one or more primary inputs; and shifting the one or more bitstreams by a selected number of bits for each test. In some embodiments, the method further comprises shifting the one or more bitstreams a length of the scan chain. In some embodiments, the method further comprises, based on the ATPG test method of the plurality of ATPG test methods comprising an overlapped ATPG test method, loading the scan chain and the one or more bitstreams simultaneously. In some embodiments, the method further comprises, based on the ATPG test method of the plurality of ATPG test methods comprising an overlapped parallel ATPG test method: loading a plurality of bits each cycle; and overlapping loading of the one or more bitstreams with loading of the scan chain. In some embodiments, the reconfigurable hardware comprises field-programmable gate arrays (FPGAs), or embedded FPGAs (e-FPGAs) used in application-specific integrated circuits (ASICs). In some embodiments, applying the one or more test patterns and the one or more bitstreams to the reconfigurable hardware design further comprises loading the one or more test patterns and the one or more bitstreams into one or more of (i) the scan chain, (ii) the primary inputs, or (iii) configuration flip-flops of the reconfigurable hardware design.

According to one embodiment, a computing system comprises memory and one or more processors communicatively coupled to the memory, the one or more processors configured to insert a scan chain into a reconfigurable hardware design associated with an integrated circuit comprising a redacted design; generate, using an automatic test pattern generation (ATPG) system, one or more test patterns and one or more bitstreams; receive one or more primary outputs and contents of the scan chain from the reconfigurable hardware design by applying the one or more test patterns and the one or more bitstreams to the reconfigurable hardware design based on an ATPG test method of a plurality of ATPG test methods and a test architecture of a plurality of test architectures; compare the one or more outputs and contents of the scan chain with one or more respective expected outcomes; and determine one or more faults associated with the reconfigurable hardware design based on the comparison.

In some embodiments, the one or more processors are further configured to, based on the ATPG test method of the plurality of ATPG test methods comprising a base ATPG test method, treat contents of one or more configuration flip-flops associated with the reconfigurable hardware design as one or more primary inputs. In some embodiments, the one or more processors are further configured to, based on the ATPG test method of the plurality of ATPG test methods comprising a shift ATPG test method: treat contents of one or more configuration flip-flops associated with the reconfigurable hardware design as one or more primary inputs; and shift the one or more bitstreams by a selected number of bits for each test. In some embodiments, the one or more processors are further configured to shift the one or more bitstreams a length of the scan chain. In some embodiments, the one or more processors are further configured to, based on the ATPG test method of the plurality of ATPG test methods comprising an overlapped ATPG test method, load the scan chain and the one or more bitstreams simultaneously. In some embodiments, the one or more processors are further configured to, based on the ATPG test method of the plurality of ATPG test methods comprising an overlapped parallel ATPG test method: load a plurality of bits each cycle, and overlap loading of the one or more bitstreams with loading of the scan chain. In some embodiments, the one or more processors are further configured to apply the one or more test patterns and the one or more bitstreams to the reconfigurable hardware design further comprises loading the one or more test patterns and the one or more bitstreams into one or more of (i) the scan chain, (ii) the primary inputs, or (iii) configuration flip-flops of the reconfigurable hardware design.

According to one embodiment, one or more non-transitory computer-readable storage media include instructions that, when executed by one or more processors, cause the one or more processors to insert a scan chain into a reconfigurable hardware design associated with an integrated circuit comprising a redacted design; generate, using an automatic test pattern generation (ATPG) system, one or more test patterns and one or more bitstreams; receive one or more primary outputs and contents of the scan chain from the reconfigurable hardware design by applying the one or more test patterns and the one or more bitstreams to the reconfigurable hardware design based on an ATPG test method of a plurality of ATPG test methods and a test architecture of a plurality of test architectures; compare the one or more outputs and contents of the scan chain with one or more respective expected outcomes; and determine one or more faults associated with the reconfigurable hardware design based on the comparison.

In some embodiments, the one or more non-transitory computer-readable storage media further include instructions that, when executed by the one or more processors, cause the one or more processors to, based on the ATPG test method of the plurality of ATPG test methods comprises a base ATPG test method, treat contents of one or more configuration flip-flops associated with the reconfigurable hardware design as one or more primary inputs. In some embodiments, the one or more non-transitory computer-readable storage media further include instructions that, when executed by the one or more processors, cause the one or more processors to, based on the ATPG test method of the plurality of ATPG test methods comprises a shift ATPG test method: treat contents of one or more configuration flip-flops associated with the reconfigurable hardware design as one or more primary inputs; and shift the one or more bitstreams by a selected number of bits for each test. In some embodiments, the one or more non-transitory computer-readable storage media further include instructions that, when executed by the one or more processors, cause the one or more processors to, based on the ATPG test method of the plurality of ATPG test methods comprises an overlapped ATPG test method, load the scan chain and the one or more bitstreams simultaneously. In some embodiments, the one or more non-transitory computer-readable storage media further include instructions that, when executed by the one or more processors, cause the one or more processors to, based on the ATPG test method of the plurality of ATPG test methods comprises an overlapped parallel ATPG test method: load a plurality of bits each cycle, and overlap loading of the one or more bitstreams with loading of the scan chain.

### BRIEF DESCRIPTION OF THE DRAWINGS

Embodiments incorporating teachings of the present disclosure are shown and described with respect to the figures presented herein.

FIG. 1 provides an example overview of an architecture in accordance with some embodiments of the present disclosure.

FIG. 2 provides an example hardware analysis computing entity in accordance with some embodiments discussed herein.

FIG. 3 provides an example client computing entity in accordance with some embodiments discussed herein.

FIG. 4 is a dataflow diagram of ATPG testing in accordance with some embodiments discussed herein.

FIG. 5 is a dataflow diagram of ATPG testing for redacted IP and reconfigurable hardware in accordance with some embodiments discussed herein.

FIG. 6 presents a flowchart of a process for evaluating performance of a reconfigurable hardware design in accordance with some embodiments discussed herein.

FIG. 7 illustrates a timing diagram of a base ATPG test method in accordance with some embodiments discussed herein.

FIG. 8 depicts an operational example of a test architecture associated with a base ATPG method in accordance with some embodiments discussed herein.

FIG. 9 illustrates a timing diagram of an overlapping ATPG test method in accordance with some embodiments discussed herein.

FIG. 10 illustrates a timing diagram of a shift ATPG test method in accordance with some embodiments discussed herein.

FIG. 11 illustrates a timing diagram of an overlapped parallel ATPG test method in accordance with some embodiments discussed herein.

FIG. 12 depicts testing time slowdown results of ATPG test methods variations used on reconfigurable hardware designs in accordance with some embodiments discussed herein.

### DETAILED DESCRIPTION

Various embodiments of the present disclosure now will be described more fully hereinafter with reference to the accompanying drawings, in which some, but not all embodiments of the disclosure are shown. Indeed, the disclosure may be embodied in many different forms and should not be construed as limited to the embodiments set forth herein. Rather, these embodiments are provided so that this disclosure will satisfy applicable legal requirements. The term “or” is used herein in both the alternative and conjunctive sense, unless otherwise indicated. The terms “illustrative,” “example,” and “exemplary” are used to be examples with no indication of quality level. Like numbers refer to like elements throughout.

### General Overview and Exemplary Technical Improvements

ATPG may comprise an electronic design automation method/technology used to find an input (or test) sequence that, when applied to a digital circuit, enables automatic test equipment to distinguish between correct circuit behavior and the faulty circuit behavior caused by defects. ATPG may be used to test semiconductor devices after manufacture, or to assist with determining the cause of failure. The effectiveness of the ATPG may be measured primarily by the fault coverage achieved and the cost of performing the test.

The present application discloses techniques that build on top of existing ATPG tools to minimize the amount of testing time required to maximize coverage for stuck-at faults in redacted IP, without requiring any knowledge of the original design, and while integrating into existing DFT flows more easily than existing approaches.

### Exemplary Technical Implementation of Various Embodiments

Embodiments of the present disclosure may be implemented in various ways, including as computer program products that comprise articles of manufacture. Such computer program products may include one or more software components including, for example, software objects, methods, data structures, and/or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid state drive (SSD), solid state card (SSC), solid state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatus, systems, computing devices, computing entities, and/or the like. As such, embodiments of the present disclosure may take the form of a data structure, apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described with reference to example operations, steps, processes, blocks, and/or the like. Thus, it should be understood that each operation, step, process, block, and/or the like may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some exemplary embodiments, retrieval, loading, and/or execution may be performed in parallel such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

### Exemplary System Architecture

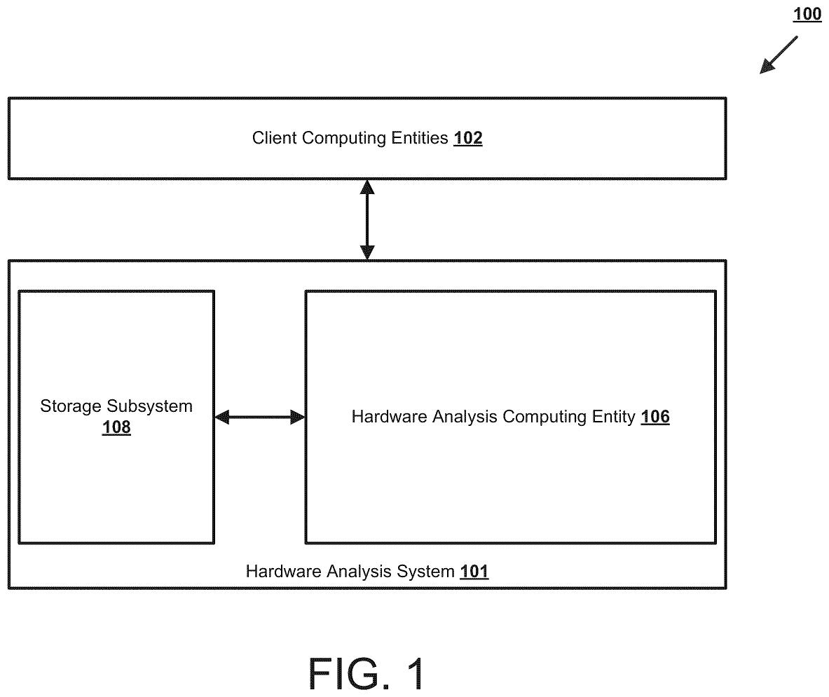

FIG. 1 is a schematic diagram of an example architecture 100 for testing design redacting reconfigurable hardware. The architecture 100 includes a hardware analysis system 101 configured to receive hardware testing requests from client computing entities 102, process the hardware testing requests to generate hardware tests, provide the generated hardware tests to the client computing entities 102.

For example, in accordance with various embodiments of the present disclosure, improved ATPG methods may be executed to better handle design redacting reconfigurable hardware. In doing so, the techniques described herein improving efficiency and speed of testing design redacting reconfigurable hardware, thus reducing the number of computational operations needed. Accordingly, the techniques described herein improve at least one of the computational efficiency, storage-wise efficiency, and speed of performing hardware tests.

In some embodiments, hardware analysis system 101 may communicate with at least one of the client computing entities 102 using one or more communication networks. Examples of communication networks include any wired or wireless communication network including, for example, a wired or wireless local area network (LAN), personal area network (PAN), metropolitan area network (MAN), wide area network (WAN), or the like, as well as any hardware, software and/or firmware required to implement it (such as, e.g., network routers, and/or the like).

The hardware analysis system 101 may include a hardware analysis computing entity 106 and a storage subsystem 108. The hardware analysis computing entity 106 may be configured to receive hardware testing requests from one or more client computing entities 102, process the hardware testing requests to generate hardware tests corresponding to the hardware testing requests, provide the generated hardware tests to the client computing entities 102.

The storage subsystem 108 may be configured to store input data used by the hardware analysis computing entity 106 to perform hardware analysis. The storage subsystem 108 may include one or more storage units, such as multiple distributed storage units that are connected through a computer network. Each storage unit in the storage subsystem 108 may store at least one of one or more data assets and/or one or more data about the computed properties of one or more data assets. Moreover, each storage unit in the storage subsystem 108 may include one or more non-volatile storage or memory media including, but not limited to, hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

### Exemplary Hardware Analysis Computing Entity

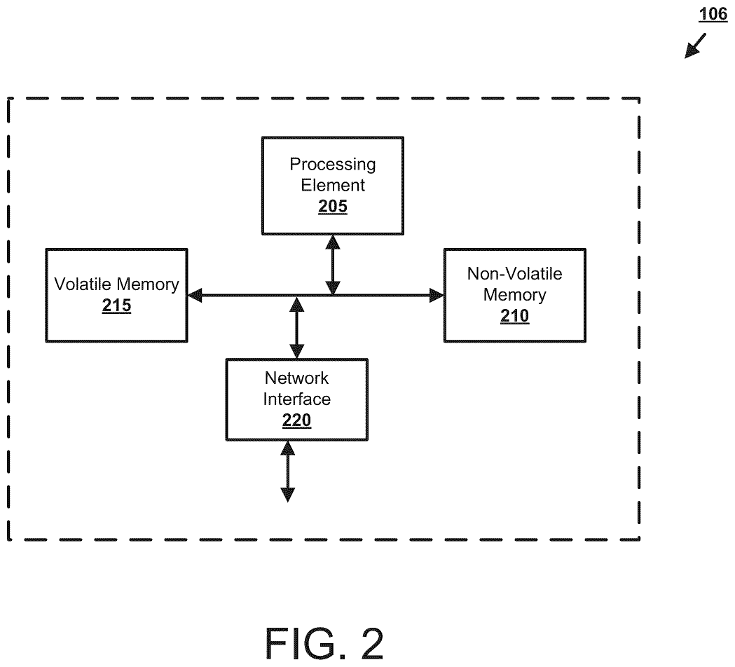

FIG. 2 provides a schematic of a hardware analysis computing entity 106 according to one embodiment of the present disclosure. In general, the terms computing entity, computer, entity, device, system, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

As indicated, in one embodiment, the hardware analysis computing entity 106 may also include one or more network interfaces 220 for communicating with various computing entities, such as by communicating data, content, information, and/or similar terms used herein interchangeably that can be transmitted, received, operated on, processed, displayed, stored, and/or the like.

As shown in FIG. 2, in one embodiment, the hardware analysis computing entity 106 may include, or be in communication with, one or more processing elements 205 (also referred to as processors, processing circuitry, and/or similar terms used herein interchangeably) that communicate with other elements within the hardware analysis computing entity 106 via a bus, for example. As will be understood, the processing element 205 may be embodied in a number of different ways.

For example, the processing element 205 may be embodied as one or more complex programmable logic devices (CPLDs), microprocessors, multi-core processors, coprocessing entities, application-specific instruction-set processors (ASIPs), microcontrollers, and/or controllers. Further, the processing element 205 may be embodied as one or more other processing devices or circuitry. The term circuitry may refer to an entirely hardware embodiment or a combination of hardware and computer program products. Thus, the processing element 205 may be embodied as integrated circuits, application specific integrated circuits (ASICs), field programmable gate arrays (FPGAs), programmable logic arrays (PLAs), hardware accelerators, other circuitry, and/or the like.

As will therefore be understood, the processing element 205 may be configured for a particular use or configured to execute instructions stored in volatile or non-volatile media or otherwise accessible to the processing element 205. As such, whether configured by hardware or computer program products, or by a combination thereof, the processing element 205 may be capable of performing steps or operations according to embodiments of the present disclosure when configured accordingly.

In one embodiment, the hardware analysis computing entity 106 may further include, or be in communication with, non-volatile media (also referred to as non-volatile storage, memory, memory storage, memory circuitry and/or similar terms used herein interchangeably). In one embodiment, the non-volatile storage or memory may include one or more non-volatile storage or memory media 210, including, but not limited to, hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

As will be recognized, the non-volatile storage or memory media may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

In one embodiment, the hardware analysis computing entity 106 may further include, or be in communication with, volatile media (also referred to as volatile storage, memory, memory storage, memory circuitry and/or similar terms used herein interchangeably). In one embodiment, the volatile storage or memory may also include one or more volatile storage or memory media 215, including, but not limited to, RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like.

As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, the processing element 205. Thus, the databases, database instances, database management systems, data, applications, programs, program modules, scripts, source code, object code, byte code, compiled code, interpreted code, machine code, executable instructions, and/or the like may be used to control certain aspects of the operation of the hardware analysis computing entity 106 with the assistance of the processing element 205 and operating system.

As indicated, in one embodiment, the hardware analysis computing entity 106 may also include one or more network interfaces 220 for communicating with various computing entities, such as by communicating data, content, information, and/or similar terms used herein interchangeably that can be transmitted, received, operated on, processed, displayed, stored, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the hardware analysis computing entity 106 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

Although not shown, the hardware analysis computing entity 106 may include, or be in communication with, one or more input elements, such as a keyboard input, a mouse input, a touch screen/display input, motion input, movement input, audio input, pointing device input, joystick input, keypad input, and/or the like. The hardware analysis computing entity 106 may also include, or be in communication with, one or more output elements (not shown), such as audio output, video output, screen/display output, motion output, movement output, and/or the like.

### Exemplary Client Computing Entity

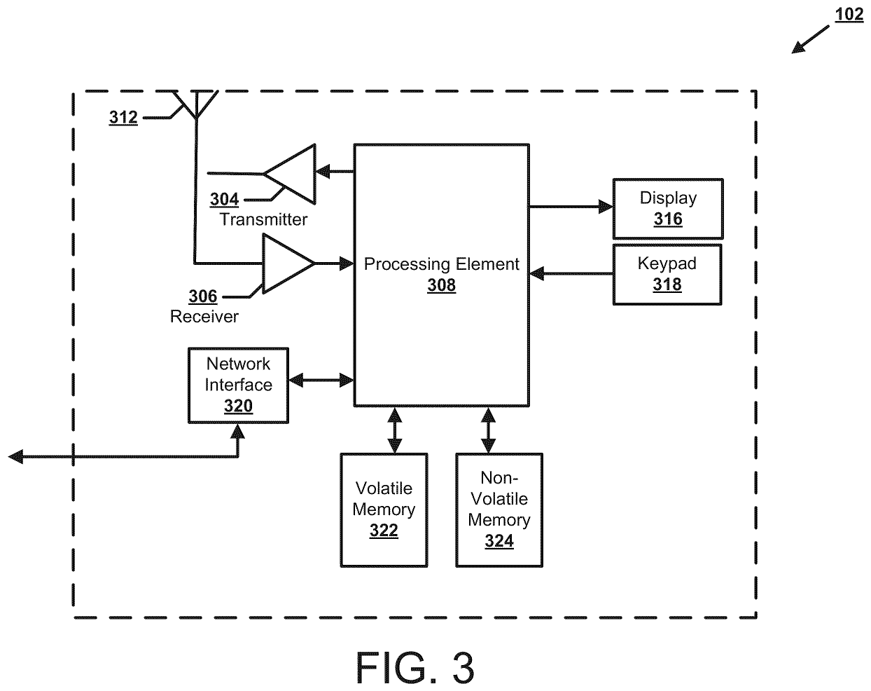

FIG. 3 provides an illustrative schematic representative of a client computing entity 102 that can be used in conjunction with embodiments of the present disclosure. In general, the terms device, system, computing entity, entity, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Client computing entities 102 can be operated by various parties. As shown in FIG. 3, the client computing entity 102 can include an antenna 312, a transmitter 304 (e.g., radio), a receiver 306 (e.g., radio), and a processing element 308 (e.g., CPLDs, microprocessors, multi-core processors, coprocessing entities, ASIPs, microcontrollers, and/or controllers) that provides signals to and receives signals from the transmitter 304 and receiver 306, correspondingly.

The signals provided to and received from the transmitter 304 and the receiver 306, correspondingly, may include signaling information/data in accordance with air interface standards of applicable wireless systems. In this regard, the client computing entity 102 may be capable of operating with one or more air interface standards, communication protocols, modulation types, and access types. More particularly, the client computing entity 102 may operate in accordance with any of a number of wireless communication standards and protocols, such as those described above with regard to the hardware analysis computing entity 106. In a particular embodiment, the client computing entity 102 may operate in accordance with multiple wireless communication standards and protocols, such as UMTS, CDMA2000, 1×RTT, WCDMA, GSM, EDGE, TD-SCDMA, LTE, E-UTRAN, EVDO, HSPA, HSDPA, Wi-Fi, Wi-Fi Direct, WiMAX, UWB, IR, NFC, Bluetooth, USB, and/or the like. Similarly, the client computing entity 102 may operate in accordance with multiple wired communication standards and protocols, such as those described above with regard to the hardware analysis computing entity 106 via a network interface 320.

Via these communication standards and protocols, the client computing entity 102 can communicate with various other entities using concepts such as Unstructured Supplementary Service Data (USSD), Short Message Service (SMS), Multimedia Messaging Service (MMS), Dual-Tone Multi-Frequency Signaling (DTMF), and/or Subscriber Identity Module Dialer (SIM dialer). The client computing entity 102 can also download changes, add-ons, and updates, for instance, to its firmware, software (e.g., including executable instructions, applications, program modules), and operating system.

The client computing entity 102 may also comprise a user interface (that can include a display 316 coupled to a processing element 308) and/or a user input interface (coupled to a processing element 308). For example, the user interface may be a user application, browser, user interface, and/or similar words used herein interchangeably executing on and/or accessible via the client computing entity 102 to interact with and/or cause display of information/data from the hardware analysis computing entity 106, as described herein. The user input interface can comprise any of a number of devices or interfaces allowing the client computing entity 102 to receive data, such as a keypad 318 (hard or soft), a touch display, voice/speech or motion interfaces, or other input device. In embodiments including a keypad 318, the keypad 318 can include (or cause display of) the conventional numeric (0-9) and related keys (#, *), and other keys used for operating the client computing entity 102 and may include a full set of alphabetic keys or set of keys that may be activated to provide a full set of alphanumeric keys. In addition to providing input, the user input interface can be used, for example, to activate or deactivate certain functions, such as screen savers and/or sleep modes.

The client computing entity 102 can also include volatile storage or memory 322 and/or non-volatile storage or memory 324, which can be embedded and/or may be removable. For example, the non-volatile memory may be ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. The volatile and non-volatile storage or memory can store databases, database instances, database management systems, data, applications, programs, program modules, scripts, source code, object code, byte code, compiled code, interpreted code, machine code, executable instructions, and/or the like to implement the functions of the client computing entity 102. As indicated, this may include a user application that is resident on the entity or accessible through a browser or other user interface for communicating with the hardware analysis computing entity 106 and/or various other computing entities.

In another embodiment, the client computing entity 102 may include one or more components or functionality that are the same or similar to those of the hardware analysis computing entity 106, as described in greater detail above. As will be recognized, these architectures and descriptions are provided for exemplary purposes only and are not limiting to the various embodiments.

### Exemplary System Operations

Various embodiments of the present disclosure describe steps, operations, processes, methods, functions, and/or the like for testing hardware IP.

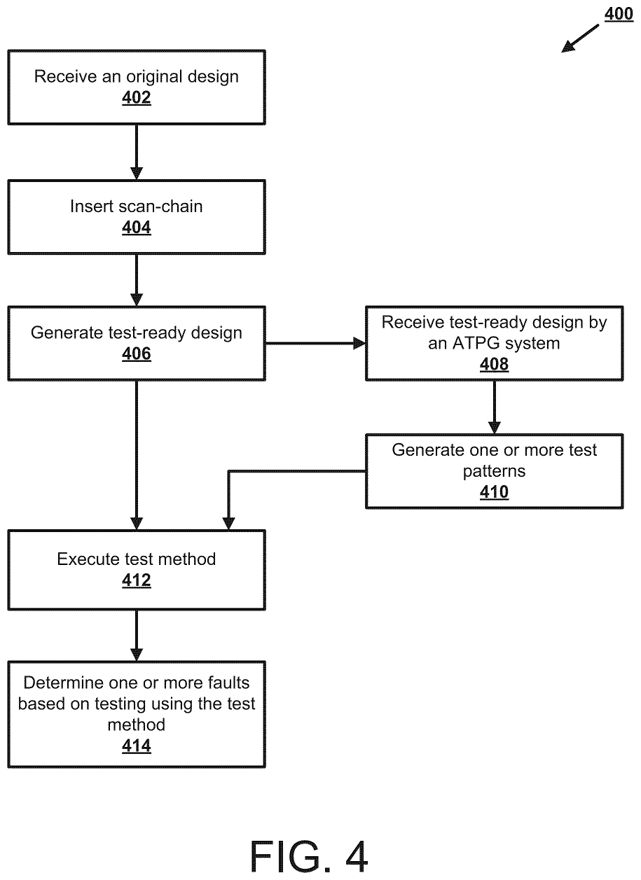

FIG. 4 is a dataflow diagram of ATPG testing in accordance with some embodiments discussed herein.

In some embodiments, the process 400 begins at step/operation 402, when an original design is received.

In some embodiments, at step/operation 404, the original design is passed to scan chain insertion to insert a scan chain into the original design by creating a shift register out of design flips-flops to enable loading and monitoring of values during testing.

In some embodiments, at step/operation 406, a test-ready design is generated based on the scan chain insertion.

In some embodiments, at step/operation 408, the test-ready design is received by an ATPG system that analyzes the test-ready design.

In some embodiments, at step/operation 410, one or more test patterns comprising scan chain contents and primary inputs are generated based on the analysis by ATPG.

In some embodiments, at step/operation 412, an ATPG test method is executed to apply one or more test patterns from the ATPG to the test-ready design by loading in scan chain contents for one or more tests and then applying one or more primary inputs. Contents of the scan chain may be scanned out while also saving values of primary outputs. The ATPG test method may then compare the values of the primary outputs with known correct values provided by the ATPG via the one or more test patterns. The ATPG test method may repeat testing for every test provided by ATPG (e.g., one or more test patterns), with the number of tests determined by the desired level of fault coverage.

In some embodiments, at step/operation 414, one or more faults associated with the original design are determined based on testing using the ATPG test method.

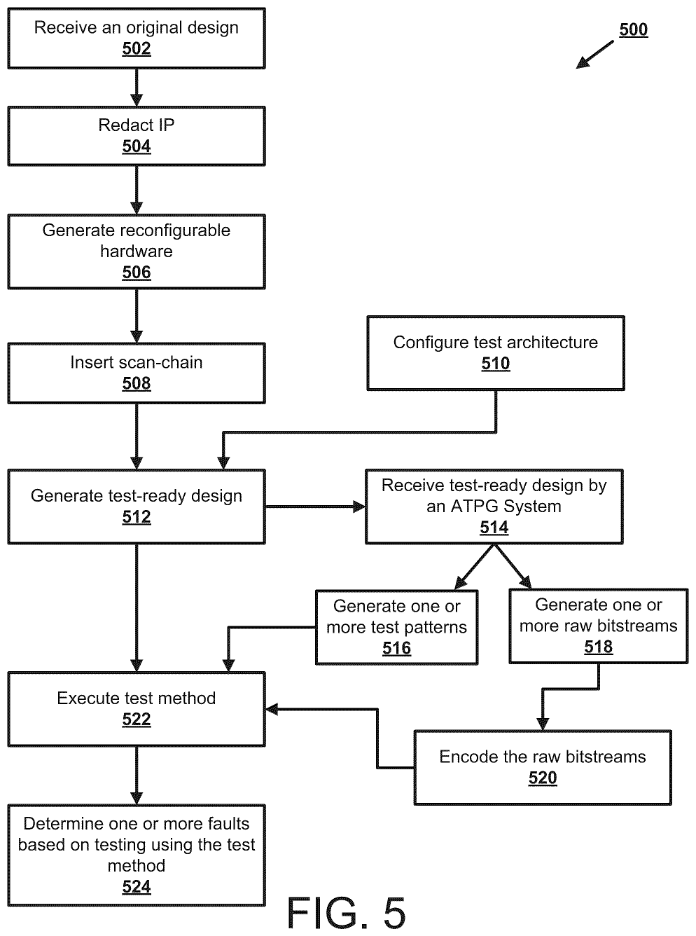

FIG. 5 is a dataflow diagram of ATPG testing for redacted IP and reconfigurable hardware in accordance with some embodiments discussed herein.

In some embodiments, the process 500 begins at step/operation 502, when an original design is received.

In some embodiments, at step/operation 504, the original design is passed to a redaction tool that replaces the application's logic associated with the original design with reconfigurable hardware.

In some embodiments, at step/operation 506, reconfigurable hardware is generated based on the redaction of the original design performed at step/operation 504. Alternatively, in the case of reconfigurable hardware without explicit IP redaction, reconfigurable hardware is received at step/operation 506.

In some embodiments, at step/operation 508, the reconfigurable hardware is passed to scan chain insertion for inserting a scan chain into the reconfigurable hardware.

In some embodiments, at step/operation 510, a test architecture is configured. A test architecture may be necessary because unlike normal ASICs that may load a scan chain serially, reconfigurable hardware may also require loading a bitstream, which contains additional configuration and error-checking logic. Traditional ATPG may assume a set of primary inputs and scan chain for a design under test, which may require a simple test architecture comprising loading the scan chain, applying the primary inputs, and verifying primary outputs and scan chain content. Using ATPG for reconfigurable hardware may require a more complicated test architecture than traditional ATPG. That is, according to various embodiments of the present disclosure, in addition to having to load a scan chain, a test architecture may be used to configure reconfigurable hardware with a bitstream.

According to various embodiments of the present disclosure, the configured test architecture is selected from a plurality of test architectures based on a desired ATPG test method to be used for applying test patterns to a test-ready design. The exact functionality of a test architecture may vary across ATPG test methods, but in general, each ATPG test method may use a test architecture to load a test pattern into a scan chain of a reconfigurable hardware, in addition to loading a bitstream. However, loading the bitstream may require additional logic depending on the exact reconfigurable hardware architecture and application. In some embodiments, a test architecture may comprise a configuration controller configured to encode raw bitstreams into configuration bits or a format suitable for testing a given reconfigurable hardware design.

In some embodiments, at step/operation 512, a test-ready design is generated based on the scan chain insertion and the test architecture.

In some embodiments, at step/operation 514, the test-ready design is received by an ATPG system that analyzes the test-ready design.

In some embodiments, at step/operation 516, one or more test patterns comprising scan chain contents and primary inputs are generated by the ATPG system based on the test-ready design.

In some embodiments, at step/operation 518, in addition to the scan chain contents and primary inputs, one or more raw bitstreams are generated by the ATPG system to test functionality of the reconfigurable hardware.

In some embodiments, at step/operation 520, one or more encoded bitstreams are generated by encoding the one or more raw bitstreams. The one or more raw bitstreams may be encoded according to a format expected or suitable for the reconfigurable hardware.

In some embodiments, at step/operation 522, an ATPG test method is executed to apply the one or more test patterns and the one or more encoded bitstreams to the test-ready design. According to various embodiments of the present disclosure, an ATPG test method comprises an extension to ATPG or modified ATPG configured to better handle reconfigurable hardware for redacted IP.

In some embodiments, at step/operation 524, one or more faults associated with the reconfigurable hardware, or the original design are determined based on testing using the ATPG test method that leverages the test-ready design, the test architecture, the one or more test patterns, and the one or more bitstreams.

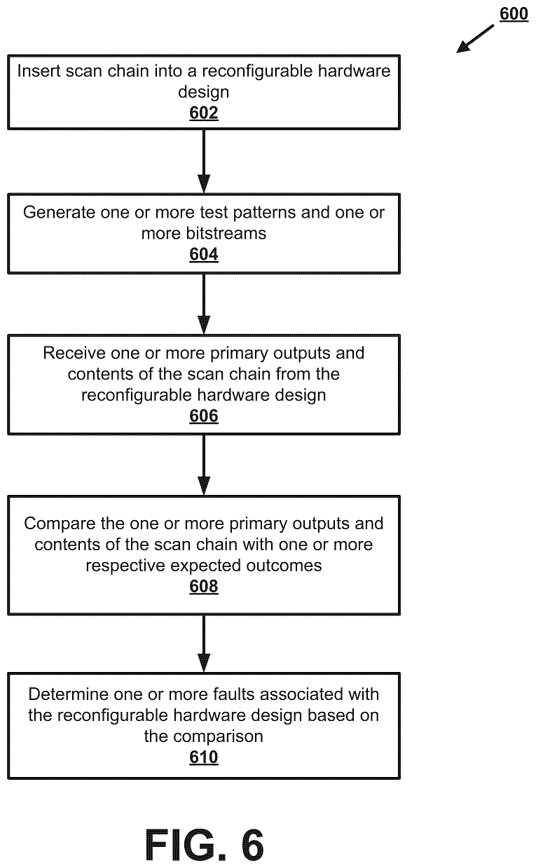

FIG. 6 presents a flowchart of a process for evaluating performance of a reconfigurable hardware design in accordance with some embodiments discussed herein.

The process 600 includes example operations that may be performed by the hardware analysis computing entity 106, and the hardware analysis computing entity 106 comprises means, such as processing element 205, memories 210 and 215, network interface 220, and/or the like, for performing the example operations.

In some embodiments, the process 600 begins at step/operation 602 when the hardware analysis computing entity 106 inserts a scan chain into a reconfigurable hardware design. Inserting the scan chain into the reconfigurable hardware design may comprise inserting one or more flip-flops (e.g., scan cells) in serial thereby generating one or more shift registers to test the reconfigurable hardware design. Examples of devices comprising reconfigurable hardware include field-programmable gate arrays (FPGAs), embedded FPGAs (e-FPGAs) used in application-specific integrated circuits (ASICs), or any other hardware device comprising logic gates with customizable functionality at run-time. In some embodiments, the reconfigurable hardware design comprises a redacted design of an integrated circuit. For example, an application's logic associated with an original design may be replaced with reconfigurable hardware comprising one or more look-up tables.

A scan chain may comprise scan cells created by modifying memory cells, such as flipflops or latches, in the reconfigurable hardware design and adding various modes (e.g., functional mode and test mode) to control the flip-flop contents. The scan cells may be connected together to form the scan chain which may operate as shift registers when configured in a test mode. Scan chains may be used in integrated circuit design to enhance testability and facilitate diagnosis. A scan chain may facilitate easier testing by providing a way to set and observe every flip-flop in an integrated circuit.

In some embodiments, at step 604, one or more test patterns and one or more bitstreams are generated for the scan chain-inserted reconfigurable hardware design by an ATPG system. The one or more test patterns and the one or more bitstreams may be used to test the scan chain-inserted reconfigurable hardware using a given test architecture. According to various embodiments of the present disclosure, the test architecture may be selected from a plurality of test architectures based on a desired ATPG test method to be used for applying test patterns and bitstreams to the reconfigurable hardware design. The ATPG system may comprise electronic design automation system used to generate an input or test sequence that, when applied to a digital circuit such as the reconfigurable hardware design, enables automatic test equipment to distinguish between correct circuit behavior and faulty circuit behavior caused by defects. An automatic test equipment may comprise computer-controlled test instruments (associated with real or simulated devices) capable of automatically testing and diagnosing faults based on output generated by a tested reconfigurable hardware design in response to test patterns and bitstreams, e.g., generated by the ATPG system.

In some embodiments, at step 606, one or more primary outputs and contents of the scan chain are received from the reconfigurable hardware design by applying the one or more test patterns and the one or more bitstreams to the scan chain-inserted reconfigurable hardware design based on an ATPG test method of a plurality of ATPG test methods and a test architecture of a plurality of test architectures. Applying the one or more test patterns and the one or more bitstreams to the scan chain-inserted reconfigurable hardware design may comprise loading the one or more test patterns and the one or more bitstreams into respective ones of the scan chain, the primary inputs, or the bitstream of the scan chain-inserted reconfigurable hardware design. For example, scan cells may be initialized with one or more test scan chain values via scan chain loading, one or more test primary input values may be applied to the primary inputs, and one or more bitstreams may be loaded into one or more configuration flip-flops. In some embodiments, the one or more bitstreams may be encoded prior to loading into the scan chain-inserted reconfigurable hardware design.

Scan cells of the scan chain can be operated in two modes, a functional mode used during normal operation and a test mode that allows shifting through the scan chain. The scan chain may be used by automatic test equipment to deliver the one or more test patterns to the reconfigurable hardware design. Test patterns in the set may be iterated through the reconfigurable hardware design. In one embodiment, for each test pattern, the test pattern may be loaded to the primary inputs of the reconfigurable hardware design while in test mode. After loading the test pattern, the reconfigurable hardware design may be switched into functional mode to generate a test response. After each test pattern iteration, the reconfigurable hardware design may be configured in test mode and a current test response is shifted out, while a next test pattern is simultaneously shifted into the scan cells.

According to various embodiments of the present disclosure, at least one ATPG test method of a plurality of ATPG test methods for loading the one or more test patterns and the one or more bitstreams into the scan chain-inserted reconfigurable hardware design may be used based on a desired fault coverage, testing time, or and/or any other performance criteria. An ATPG test method may be performed by using a test architecture corresponding to the ATPG test. For example, the test architecture may provide a guide in which an ATPG test method may be performed on a design for testing (e.g., a reconfigurable hardware design).

In one embodiment, a “base” ATPG test method comprises treating the contents of each configuration flip-flop of an integrated circuit associated with the reconfigurable hardware design as a primary input. With this approach, ATPG algorithms may be used to determine scan chain contents, bitstream contents, in addition to primary input values for each test. This approach may be effective at minimizing the number of total tests to achieve a desired fault coverage.

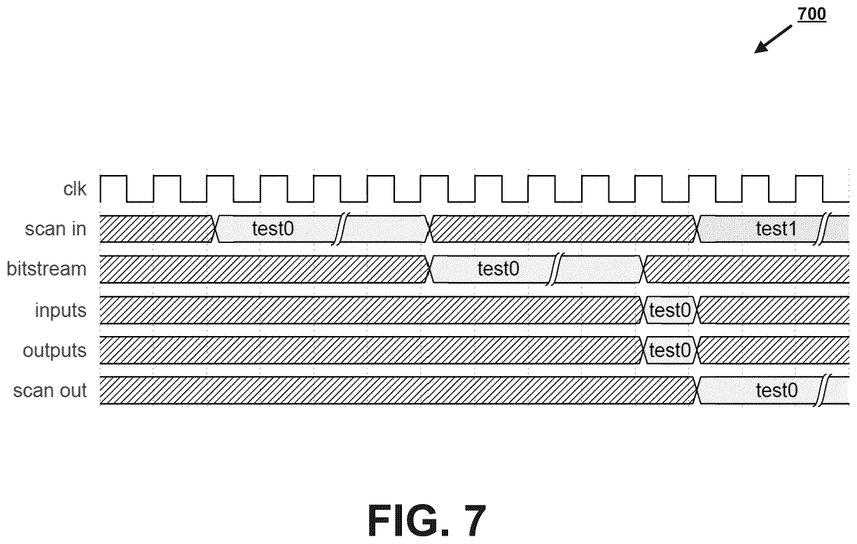

FIG. 7 illustrates a timing diagram of a base ATPG test method in accordance with some embodiments discussed herein. As depicted in FIG. 7, a configuration chain 700 is provided with data signals using a base ATPG test method. The base ATPG test method first loads (“scan in”) scan chain contents for a “test0.” Upon completion, the base ATPG test method leverages a configuration controller within a test architecture to serially load a bitstream for “test0.” Next, the base ATPG test method applies primary inputs and checks all primary outputs, which may require two stages. The base ATPG method may sample the primary outputs for comparison with correct values to identify faults. The base ATPG method may repeat the process for a next test by simultaneously shifting out the contents of the scan chain (“scan out”) for “test0” and loading scan chain contents for a next “test1.”

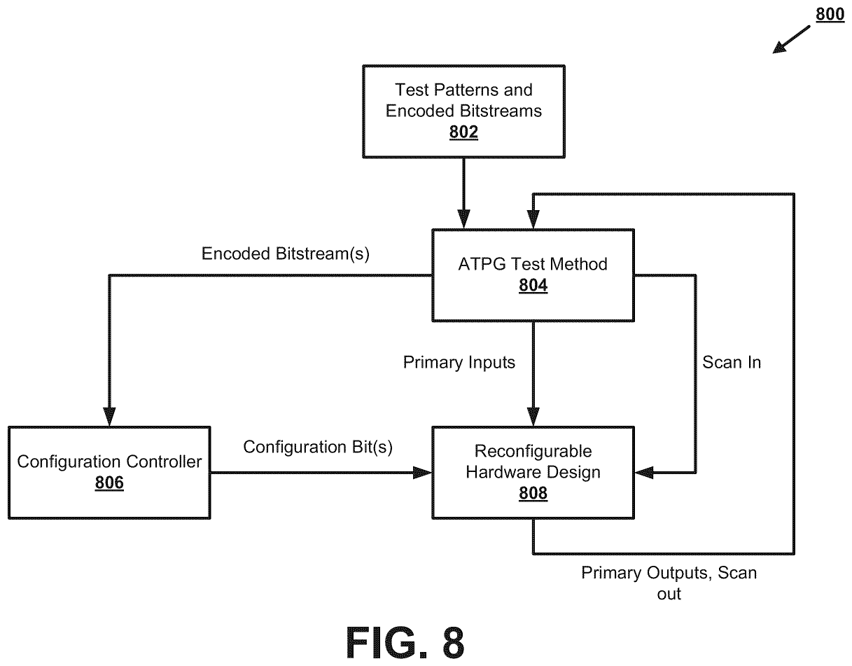

FIG. 8 depicts an operational example of a test architecture 800 associated with a base ATPG method in accordance with some embodiments discussed herein.

A scan chain interface with reconfigurable hardware design 808 may be generated (e.g., by using design for testing tools) for loading primary inputs, scan in content (e.g., scan chain loading), and configuration bits into reconfigurable hardware design 808 by a ATPG test method 804. The ATPG test method 804 may generate and provide the primary inputs and the scan in content to reconfigurable hardware design 808 based on test patterns from test patterns and encoded bitstreams 802. ATPG may further provide encoded bitstreams to configuration controller 806 where the configuration controller 806 provides a mechanism for the ATPG test method 804 to shift in bitstreams to the reconfigurable hardware design 808 via configuration bits. Primary outputs and scan chain content values may be read from the reconfigurable hardware design 808 by ATPG test model 804 and used for comparison with expected values to determine one or more faults.

According to another embodiment, an “overlapped” ATPG test method comprises loading a scan chain and a bitstream at the same time. A primary test-time bottleneck of the base ATPG method may be reduced by reducing the lengthy loading times of the scan chain and bitstream. The overlapped ATPG test method may require a test architecture configured to load the bitstream and scan chain in parallel. Simultaneous loading of the scan chain and bitstream may require minimal overhead in the test architecture given that the test architecture may already provide mechanisms to load bitstreams and scan chains. For example, the test architecture 800 depicted in FIG. 8 may be modified by adding extra control logic and increased I/O requirements to load both resources in parallel.

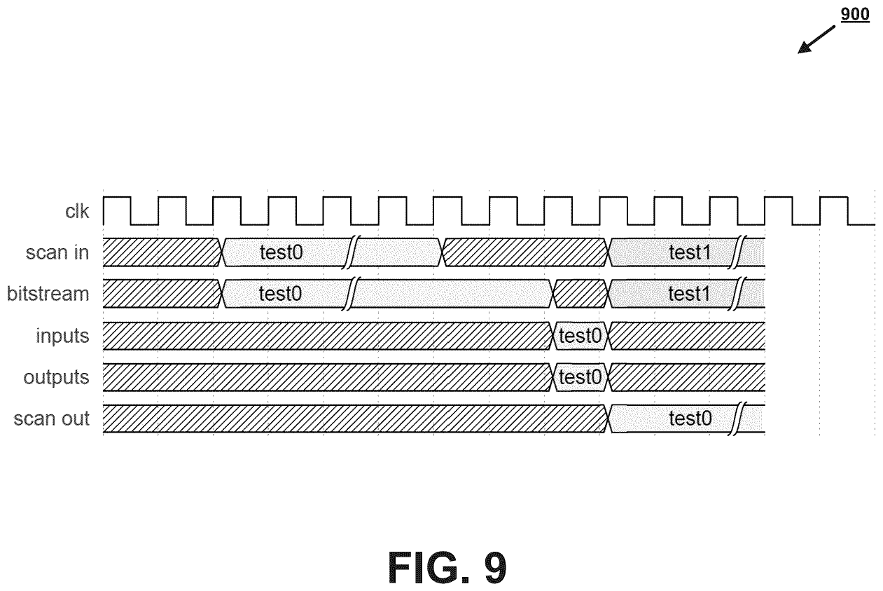

FIG. 9 illustrates a timing diagram of an overlapping ATPG test method in accordance with some embodiments discussed herein. As depicted in FIG. 9, a configuration chain 900 is provided with data signals using an overlapped ATPG test method. Initially, the overlapped ATPG test method loads the scan chain (“scan in”) and bitstream for “test0” at the same time, where the bitstream will generally take longer than the scan chain. The overlapping ATPG test method may reduce testing times of the base ATPG method by loading the bitstream and scan chain simultaneously. After loading the scan chain and the bitstream, the remainder of the method is similar to the base ATPG test method, with the “scan out” of “test0” and “scan in” of “test1” occurring simultaneously.

According to yet another embodiment, a “shift” ATPG test method comprises treating configuration flip-flops as primary inputs, but instead of using patterns directly and shifting the entire bitstream for every test (according to base ATPG test method), the bitstream may be shifted by some fixed number of bits for each test. Since scan chain contents are scanned out for every test, a logical choice for a bitstream shift amount in between tests may comprise a length of a scan chain. Shifting in an entire bitstream for every test can make testing time prohibitively long, especially if testing requires a large number of tests to achieve sufficient coverage. As such, the shift ATPG test method sacrifices coverage per test for a reduced time overhead to apply a test. Shift ATPG test method can potentially reduce testing time as long as the improvement in time for the entire test outweighs the increase in number of required tests.

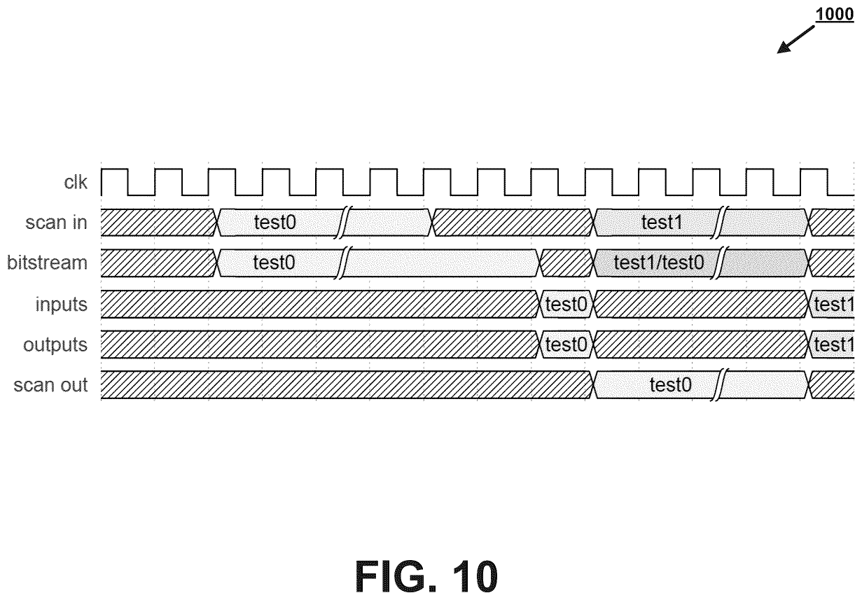

FIG. 10 illustrates a timing diagram of a shift ATPG test method in accordance with some embodiments discussed herein. As depicted in FIG. 10, a configuration chain 1000 is provided with data signals using a shift ATPG test method. The shift ATPG test method loads in both a bitstream and scan chain contents (into “scan in”) for a “test0” simultaneously. However, for a next test, “test1,” the shift ATPG test method does not load in an entirely new bitstream. Instead, the shift ATPG test method shifts the configuration chain by an amount equal to the scan chain, while partially loading in the bitstream for “test 1.” That is, the shift ATPG test method overlaps the loading of the scan chain and bitstream, but instead of loading in an entire new bitstream for a next test, it stops after the scan chain is completely loaded and treats the current state of the configuration bits as a new bitstream. By stopping the bitstream loading once the scan chain has been loaded, the shift ATPG test method reduces time for each individual test at the cost of an increase in the total number of tests. In particular, the shift ATPG test method comes at the cost of not always using bitstreams determined by ATPG tools. As a result, the shift ATPG test method sacrifices coverage per test to reduce the time to apply each test. As long as the improvement in time per test outweighs the increase in number of required tests, then shift ATPG test method may reduce testing time.

In some embodiments, a test architecture associated with a shift ATPG test method comprises a configuration controller configured to receive one or more control signals to allow the shift ATPG test method to halt the configuration of the bitstream as soon as the scan chain contents are loaded. In some other embodiments, to make the shift ATPG test method work with ATPG, scripts may be generated that insert additional tests in between ATPG-generated tests that provide the intermediate values of the configuration flip-flops after each shift. For each of the inserted tests, the bitstream contents may be constrained to ensure that STPG generates appropriate scan chain contents and primary inputs for the partially shifted bitstream. In addition, by shifting the bitstream by an amount equal to the length of the scan chain, the number of configuration flips-flops may be required to be a multiple of the length of the scan chain. To ensure that the number of configuration flips-flops is a multiple of the length of the scan chain, “dummy” configuration flip-flops may be added to a reconfigurable hardware design to create a significant area overhead when the bitstream length is not a multiple of the scan chain length.

According to yet another embodiment, an “overlapped parallel” ATPG test method may comprise the overlapped ATPG test method combined with parallel bitstream loading. The overlapped parallel ATGP test method may address testing bottleneck caused by loading of the bitstream. In particular, the overlapped parallel ATPG test method may comprise loading multiple bitstream bits each cycle and overlapping bitstream loading with loading of the scan chain, testing times may be significantly reduced. Loading of the bitstream may generally be the biggest testing bottleneck. By loading multiple bitstream bits each cycle and overlapping that loading with the loading of a scan chain, times for each test may be significantly reduced.

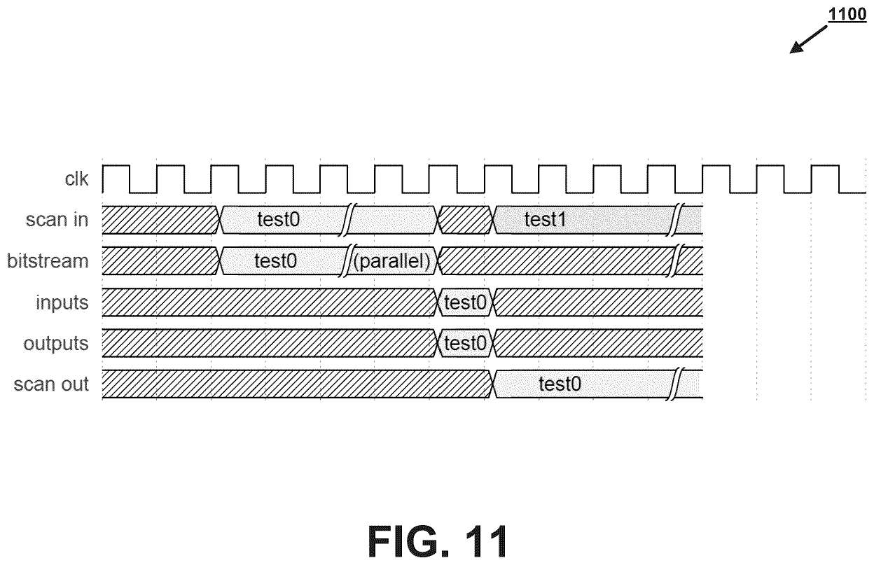

FIG. 11 illustrates a timing diagram of an overlapped parallel ATPG test method in accordance with some embodiments discussed herein. As depicted in FIG. 11, a configuration chain 1100 is provided with data signals using an overlapped parallel ATPG test method. The timing may be largely similar to the overlapped ATPG test method with the exception of the loading time of the bitstream being reduced via parallel loading, which may significantly reduce the time to apply each test. That is, potentially any number of bitstream bits may be loaded every cycle. Although arbitrary amounts of parallelism may be leveraged, reducing the bitstream loading times beyond a time required for the scan chain may not be needed because the total time to apply a test would be identical.

In some embodiments, a test architecture associated with an overlapped parallel ATPG test method comprises specialized testing circuitry for parallel testing. Reconfigurable hardware typically loads a bitstream serially into the configuration chain. To load multiple bits in parallel, two options are possible. A first option may comprise modifying the configuration chain 1100 to shift by n bits every cycle, while also using n inputs for the new bits. While this modification is conceptually simple, ASICs often use highly optimized cells for scan chains that may only shift by a single flip-flop. As a result, the first option may introduce significant area overhead.

Alternatively, a second option may comprise dividing an original bitstream into separate smaller bitstreams. The separate smaller bitstreams may be loaded into multiple configuration chains that shift by, for example, one flip-flop per cycle. While likely minimizing overhead, a test architecture for accommodating the second option may comprise a configuration controller that is configured to partition a bitstream into multiple configuration chains. Alternatively, ATPG tools used to generate the bitstream may be given knowledge of the testing architecture to generate each individual bitstream.

Returning to FIG. 6, in some embodiments, at step 608, the one or more primary outputs and contents of the scan chain are compared with one or more respective expected outcomes. Responses generated based on the one or more test patterns and the one or more bitstreams may be captured by the automatic test equipment. The automatic test equipment may compare the captured test responses with expected response data of the reconfigurable hardware design.

In some embodiments, at step 610, one or more faults associated with the reconfigurable hardware design are determined based on the comparison of the one or more primary outputs and scan chain contents with the expected outcome. That is, mismatches based on the comparison may be determined as faults. In some embodiments, the mismatches may be logged for further evaluation.

### Example Experimental Implementation of Various Embodiments

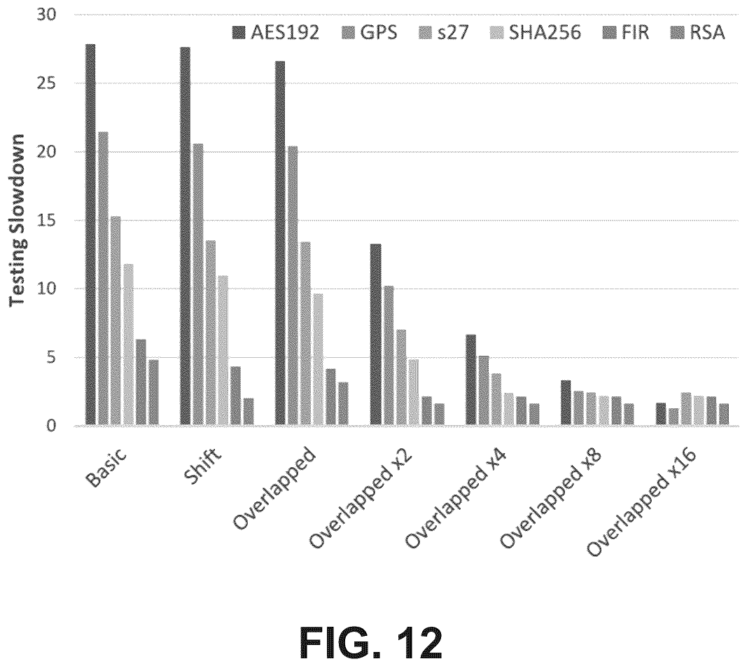

FIG. 12 depicts testing time slowdown results of ATPG test methods variations used on reconfigurable hardware designs according to various embodiments of the present disclosure. The results depicted in FIG. 12 further include results of experiments using base, shift, overlapped, and four different parallel overlapped approaches, ranging from 2 bits per cycle (Overlapped ×2) to 16 bits per cycle (Overlapped ×16). Details regarding various experimental procedures and results are further described in the attached Appendix, which is herein incorporated by reference. Specifically, the attached Appendix illustrates various exemplary embodiments of the present disclosure.

### CONCLUSION

It should be understood that the examples and embodiments described herein are for illustrative purposes only and that various modifications or changes in light thereof will be suggested to persons skilled in the art and are to be included within the spirit and purview of this application.

Many modifications and other embodiments of the present disclosure set forth herein will come to mind to one skilled in the art to which the present disclosures pertain having the benefit of the teachings presented in the foregoing descriptions and the associated drawings. Therefore, it is to be understood that the present disclosure is not to be limited to the specific embodiments disclosed and that modifications and other embodiments are intended to be included within the scope of the appended claim concepts. Although specific terms are employed herein, they are used in a generic and descriptive sense only and not for purposes of limitation. It should be understood that the examples and embodiments in the Appendix are also for illustrative purposes and are non-limiting in nature. The contents of the Appendix are incorporated herein by reference in their entirety.

1. A method for testing reconfigurable hardware designs, the method comprising:
inserting, by one or more processors, a scan chain into a reconfigurable hardware design associated with an integrated circuit comprising a redacted design;
generating, by the one or more processors and using an automatic test pattern generation (ATPG) system, one or more test patterns and one or more bitstreams;
receiving, by the one or more processors, one or more primary outputs and contents of the scan chain from the reconfigurable hardware design by applying the one or more test patterns and the one or more bitstreams to the reconfigurable hardware design based on an ATPG test method of a plurality of ATPG test methods and a test architecture of a plurality of test architectures;
comparing the one or more outputs and contents of the scan chain with one or more respective expected outcomes; and
determining one or more faults associated with the reconfigurable hardware design based on the comparison.

2. The method of claim 1 further comprising, based on the ATPG test method of the plurality of ATPG test methods comprising a base ATPG test method, treating contents of one or more configuration flip-flops associated with the reconfigurable hardware design as one or more primary inputs.

3. The method of claim 1 further comprising, based on the ATPG test method of the plurality of ATPG test methods comprising a shift ATPG test method:
treating contents of one or more configuration flip-flops associated with the reconfigurable hardware design as one or more primary inputs; and
shifting the one or more bitstreams by a selected number of bits for each test.

4. The method of claim 3 further comprising shifting the one or more bitstreams a length of the scan chain.

5. The method of claim 1 further comprising, based on the ATPG test method of the plurality of ATPG test methods comprising an overlapped ATPG test method, loading the scan chain and the one or more bitstreams simultaneously.

6. The method of claim 1 further comprising, based on the ATPG test method of the plurality of ATPG test methods comprising an overlapped parallel ATPG test method:
loading a plurality of bits each cycle; and
overlapping loading of the one or more bitstreams with loading of the scan chain.

7. The method of claim 1, wherein the reconfigurable hardware comprises field-programmable gate arrays (FPGAs), or embedded FPGAs (e-FPGAs) used in application-specific integrated circuits (ASICs).

8. The method of claim 1, wherein applying the one or more test patterns and the one or more bitstreams to the reconfigurable hardware design further comprises loading the one or more test patterns and the one or more bitstreams into one or more of i) the scan chain, ii) the primary inputs, or iii) configuration flip-flops of the reconfigurable hardware design.

9. A computing system comprising memory and one or more processors communicatively coupled to the memory, the one or more processors configured to:
insert a scan chain into a reconfigurable hardware design associated with an integrated circuit comprising a redacted design;
generate, using an automatic test pattern generation (ATPG) system, one or more test patterns and one or more bitstreams;
receive one or more primary outputs and contents of the scan chain from the reconfigurable hardware design by applying the one or more test patterns and the one or more bitstreams to the reconfigurable hardware design based on an ATPG test method of a plurality of ATPG test methods and a test architecture of a plurality of test architectures;
compare the one or more outputs and contents of the scan chain with one or more respective expected outcomes; and
determine one or more faults associated with the reconfigurable hardware design based on the comparison.

10. The computing system of claim 9, wherein the one or more processors are further configured to, based on the ATPG test method of the plurality of ATPG test methods comprising a base ATPG test method, treat contents of one or more configuration flip-flops associated with the reconfigurable hardware design as one or more primary inputs.

11. The computing system of claim 9, wherein the one or more processors are further configured to, based on the ATPG test method of the plurality of ATPG test methods comprising a shift ATPG test method:
treat contents of one or more configuration flip-flops associated with the reconfigurable hardware design as one or more primary inputs; and
shift the one or more bitstreams by a selected number of bits for each test.

12. The computing system of claim 11, wherein the one or more processors are further configured to shift the one or more bitstreams a length of the scan chain.

13. The computing system of claim 9, wherein the one or more processors are further configured to, based on the ATPG test method of the plurality of ATPG test methods comprising an overlapped ATPG test method, load the scan chain and the one or more bitstreams simultaneously.

14. The computing system of claim 9, wherein the one or more processors are further configured to, based on the ATPG test method of the plurality of ATPG test methods comprising an overlapped parallel ATPG test method:
load a plurality of bits each cycle, and
overlap loading of the one or more bitstreams with loading of the scan chain.

15. The computing system of claim 9, wherein the one or more processors are further configured to apply the one or more test patterns and the one or more bitstreams to the reconfigurable hardware design further comprises loading the one or more test patterns and the one or more bitstreams into one or more of (i) the scan chain, (ii) the primary inputs, or (iii) configuration flip-flops of the reconfigurable hardware design.

16. One or more non-transitory computer-readable storage media including instructions that, when executed by one or more processors, cause the one or more processors to:
insert a scan chain into a reconfigurable hardware design associated with an integrated circuit comprising a redacted design;
generate, using an automatic test pattern generation (ATPG) system, one or more test patterns and one or more bitstreams;
receive one or more primary outputs and contents of the scan chain from the reconfigurable hardware design by applying the one or more test patterns and the one or more bitstreams to the reconfigurable hardware design based on an ATPG test method of a plurality of ATPG test methods and a test architecture of a plurality of test architectures;
compare the one or more outputs and contents of the scan chain with one or more respective expected outcomes; and
determine one or more faults associated with the reconfigurable hardware design based on the comparison.

17. The one or more non-transitory computer-readable storage media of claim 16 further including instructions that, when executed by the one or more processors, cause the one or more processors to, based on the ATPG test method of the plurality of ATPG test methods comprises a base ATPG test method, treat contents of one or more configuration flip-flops associated with the reconfigurable hardware design as one or more primary inputs.

18. The one or more non-transitory computer-readable storage media of claim 16 further including instructions that, when executed by the one or more processors, cause the one or more processors to, based on the ATPG test method of the plurality of ATPG test methods comprises a shift ATPG test method:
treat contents of one or more configuration flip-flops associated with the reconfigurable hardware design as one or more primary inputs; and
shift the one or more bitstreams by a selected number of bits for each test.

19. The one or more non-transitory computer-readable storage media of claim 16 further including instructions that, when executed by the one or more processors, cause the one or more processors to, based on the ATPG test method of the plurality of ATPG test methods comprises an overlapped ATPG test method, load the scan chain and the one or more bitstreams simultaneously.

20. The one or more non-transitory computer-readable storage media of claim 16 further including instructions that, when executed by the one or more processors, cause the one or more processors to, based on the ATPG test method of the plurality of ATPG test methods comprises an overlapped parallel ATPG test method:
load a plurality of bits each cycle, and
overlap loading of the one or more bitstreams with loading of the scan chain.
